(19) United States
(12) Patent Application Publication
(10) Pub. No.: US 2024/0312711 A1
(43) Pub. Date: Sep. 19, 2024

(54) ULTRAHIGH ANHARMONICITY LOW-PERMITTIVITY TUNABLE THIN-FILM

(71) Applicants: DREXEL UNIVERSITY, Philadelphia, PA (US); BAR-ILAN UNIVERSITY, Ramat Gan (IL)

(72) Inventors: Matthias FALMBIGL, Syosset, NY (US); Iryna S. GOLOVINA, Philadelphia, PA (US); Christopher J. HAWLEY, Philadelphia, PA (US); Aleksandr V. PLOKHIKH, Philadelphia, PA (US); Or SHAFIR, Ramat Gan (IL); Ilya GRINBERG, Beit Shemesh (IL); Jonathan E. SPANIER, Bala Cynwyd, PA (US)

(73) Assignees: DREXEL UNIVERSITY, Philadelphia, PA (US); BAR-ILAN UNIVERSITY, Ramat Gan (IL)

(21) Appl. No.: 18/547,015

(22) PCT Filed: Feb. 18, 2022
(86) PCT No.: PCT/US2022/017038

§ 371 Date: Aug. 18, 2023

Related U.S. Application Data
(60) Provisional application No. 63/150,770, filed on Feb. 18, 2021.

(51) Int. Cl. H01G 4/12; H01G 4/33; H01G 7/06

(52) U.S. Cl. CPC H01G 4/1227; H01G 4/33; H01G 7/06

(57) ABSTRACT

Disclosed herein are thin films and methods of forming thin films. An example thin film may comprise Ba—Ti—O configured to exhibit a structure where a distance of one or more neighboring Ti—Ti atoms is less than 3 Å.

### BACKGROUND

The exploration and understanding of structure-property relationships is the focal point of materials science and the key enabler for the development of functional materials and devices. The vast structural family of perovskites provide examples to demonstrate the power of a thorough understanding of correlations between structural features and the resulting properties.

However, perovskites have limitations and improvements are needed.

### SUMMARY

Disclosed herein are thin films and methods of forming thin films. Although not limited, as such, the thin films may comprise nanocrystalline structures, single crystalline structures, poly crystalline structures, or combinations thereof.

An example thin film may comprise Ba—Ti—O configured to exhibit a structure where a distance of one or more neighboring Ti—Ti atoms is less than 3 Å.

The thin film may comprise BaTi₂O₅.

A sample of the thin film having a thickness of 40 nanometers (nm) may exhibit a dielectric constant at zero field ε(0) of less than 100.

A sample of the thin film having a thickness of 40 nm may exhibit a dielectric constant at zero field ε(0) of less than 90.

A sample of the thin film having a thickness of 40 nm may exhibit a dielectric constant at zero field ε(0) of less than 80.

A sample of the thin film having a thickness of 40 nm may exhibit an anharmonic coefficient α of greater than 100*10⁻¹³ cm²kV⁻².

A sample of the thin film having a thickness of 40 nm may exhibit an anharmonic coefficient α of greater than 110*10⁻¹³ cm²kV⁻².

A sample of the thin film having a thickness of 40 nm may exhibit an anharmonic coefficient α of greater than 120*10⁻¹³ cm²kV⁻².

A sample of the thin film having a thickness of 40 nm may exhibit an anharmonic coefficient α of greater than 130*10⁻¹³ cm²kV⁻².

A sample of the thin film having a thickness of 40 nm may exhibit an anharmonic coefficient α of greater than 140*10⁻¹³ cm²kV⁻².

A sample of the thin film having a thickness of 40 nm may exhibit an anharmonic coefficient α of greater than 150*10⁻¹³ cm²kV⁻².

A sample of the thin film having a thickness of 40 nm may exhibit an anharmonic coefficient α of greater than 160*10⁻¹³ cm²kV⁻².

The thin film may be formed using atomic layer deposition.

An example thin film may comprise Ba—Ti—O configured to exhibit a dielectric constant at zero field ε(0) of less than 100 and an anharmonic coefficient α of greater than 100*10⁻¹³ cm²kV⁻².

The thin film may be formed using atomic layer deposition.

An example thin film may comprise Ba—Ti—O configured to exhibit a dielectric constant at zero field ε(0) of less than 100 and an anharmonic coefficient α of greater than 110*10⁻¹³ cm²kV⁻².

The thin film may be formed using atomic layer deposition.

An example thin film may comprise Ba—Ti—O configured to exhibit a dielectric constant at zero field ε(0) of less than 100 and an anharmonic coefficient α of greater than 120*10⁻¹³ cm²kV⁻².

The thin film may be formed using atomic layer deposition.

An example thin film may comprise Ba—Ti—O configured to exhibit a dielectric constant at zero field ε(0) of less than 100 and an anharmonic coefficient α of greater than 130*10⁻¹³ cm²kV⁻².

The thin film may be formed using atomic layer deposition.

An example thin film may comprise Ba—Ti—O configured to exhibit a dielectric constant at zero field ε(0) of less than 100 and an anharmonic coefficient α of greater than 140*10⁻¹³ cm²kV⁻².

The thin film may be formed using atomic layer deposition.

An example thin film may comprise Ba—Ti—O configured to exhibit a dielectric constant at zero field ε(0) of less than 100 and an anharmonic coefficient α of greater than 150*10⁻¹³ cm²kV⁻².

The thin film may be formed using atomic layer deposition.

An example thin film may comprise Ba—Ti—O configured to exhibit a dielectric constant at zero field ε(0) of less than 100 and an anharmonic coefficient α of greater than 160*10⁻¹³ cm²kV⁻².

The thin film may be formed using atomic layer deposition.

An example method of forming thin film wherein the formed thin film may comprise Ba—Ti—O configured to exhibit a structure where a distance of one or more neighboring Ti—Ti atoms is less than 3 Å.

The thin film may comprise BaTi₂O₅.

A sample of the thin film having a thickness of 40 nm may exhibit a dielectric constant at zero field ε(0) of less than 100.

A sample of the thin film having a thickness of 40 nm may exhibit a dielectric constant at zero field ε(0) of less than 90.

A sample of the thin film having a thickness of 40 nm may exhibit a dielectric constant at zero field ε(0) of less than 80.

A sample of the thin film having a thickness of 40 nm may exhibit an anharmonic coefficient α of greater than 100*10⁻¹³ cm²kV⁻².

A sample of the thin film having a thickness of 40 nm may exhibit an anharmonic coefficient α of greater than 110*10⁻¹³ cm²kV⁻².

A sample of the thin film having a thickness of 40 nm may exhibit an anharmonic coefficient α of greater than 120*10⁻¹³ cm²kV⁻².

A sample of the thin film having a thickness of 40 nm may exhibit an anharmonic coefficient α of greater than 130*10⁻¹³ cm²kV⁻².

A sample of the thin film having a thickness of 40 nm may exhibit an anharmonic coefficient α of greater than 140*10⁻¹³ cm²kV⁻².

A sample of the thin film having a thickness of 40 nm may exhibit an anharmonic coefficient α of greater than 150*10⁻¹³ cm²kV⁻².

A sample of the thin film having a thickness of 40 nm may exhibit an anharmonic coefficient α of greater than 160*10⁻¹³ cm²kV⁻².

The thin film may be formed using atomic layer deposition.

An example method of forming thin film wherein the formed thin film may comprise Ba—Ti—O configured to exhibit a dielectric constant at zero field ε(0) of less than 100 and an anharmonic coefficient α of greater than 100*10⁻¹³ cm²kV⁻².

The thin film may be formed using atomic layer deposition.

An example method of forming thin film wherein the formed thin film may comprise Ba—Ti—O configured to exhibit a dielectric constant at zero field ε(0) of less than 100 and an anharmonic coefficient α of greater than 110*10⁻¹³ cm²kV⁻².

The thin film may be formed using atomic layer deposition.

An example method of forming thin film wherein the formed thin film may comprise Ba—Ti—O configured to exhibit a dielectric constant at zero field ε(0) of less than 100 and an anharmonic coefficient α of greater than 120*10⁻¹³ cm²kV⁻².

The thin film may be formed using atomic layer deposition.

An example method of forming thin film wherein the formed thin film may comprise Ba—Ti—O configured to exhibit a dielectric constant at zero field ε(0) of less than 100 and an anharmonic coefficient α of greater than 130*10⁻¹³ cm²kV⁻².

The thin film may be formed using atomic layer deposition.

An example method of forming thin film wherein the formed thin film may comprise Ba—Ti—O configured to exhibit a dielectric constant at zero field ε(0) of less than 100 and an anharmonic coefficient α of greater than 140*10⁻¹³ cm²kV⁻².

The thin film may be formed using atomic layer deposition.

An example method of forming thin film wherein the formed thin film may comprise Ba—Ti—O configured to exhibit a dielectric constant at zero field ε(0) of less than 100 and an anharmonic coefficient α of greater than 150*10⁻¹³ cm²kV⁻².

The thin film may be formed using atomic layer deposition.

An example method of forming thin film wherein the formed thin film may comprise Ba—Ti—O configured to exhibit a dielectric constant at zero field ε(0) of less than 100 and an anharmonic coefficient α of greater than 160*10⁻¹³ cm²kV⁻².

The thin film may be formed using atomic layer deposition.

### BRIEF DESCRIPTION OF THE DRAWINGS

The following drawings show generally, by way of example, but not by way of limitation, various examples discussed in the present disclosure. In the drawings:

FIGS. 1A-1D shows example structural characterization of BaTi₂O₅ thin films.

FIGS. 2A-2D shows example Raman scattering characterization of BaTi₂O₅ thin films.

FIGS. 3A-3C shows example dielectric tunability of the BaTi₂O₅ thin film.

FIG. 4 shows leakage current density, J, as a function of applied electric field, E, for a 40 nm thick BaTi₂O₅ film.

FIGS. 5A-5B shows example graphs for dielectric constant, ε.

FIGS. 6A-6F shows C-V data for a 560 nm thick PLD-grown Ba_{0.25}Sr_{0.75}TiO₃ film collected at different temperatures at a frequency of 1 MHz.

FIG. 7 shows a region with a large BaTi₂O₅ crystallite within an MIM structure.

### DETAILED DESCRIPTION

Electrically tunable dielectric thin films in active circuits and systems are challenged by capacitance-induced delays and impedance matching requiring a lower dielectric constant. In the present disclosure an approach to increasing the intrinsic tunability of compounds containing TiO₆ octahedra by considering the influence of different connectivity among these octahedra is disclosed. Such connectivity variants in monoclinic BaTi₂O₅ thin films enable a two orders of magnitude enhancement in Ti anharmonic interaction, thereby permitting a ≈65% decrease in dielectric constant to 71 at room temperature without sacrificing tunability. Edge-sharing TiO₆ octahedra possess a much shorter Ti—Ti distance of only 2.91 Å as compared to the perovskite structure (˜4 Å), permitting large field-induced structural re-arrangement and intrinsic tunability.

The exploration and understanding of structure-property relationships is the focal point of materials science and the key enabler for the development of functional materials and devices. The vast structural family of perovskites provide examples to demonstrate the power of a thorough understanding of correlations between structural features and the resulting properties. Technically as well as fundamentally interesting and relevant properties for these structures span over a wide range encompassing ferroic displacements, ion conduction, magnetism, and high-temperature superconductivity.

One example of ferroic displacement is BaTiO₃, a thin-film oxide material. BaTiO₃-based compounds may be interesting because of the polarizability of the TiO₆ octahedra, which are responsible for the ferroelectricity below the Curie temperature (T_{C}) and the corresponding nonlinear electric field dependence. As an example, the chemically substituted variant Ba₁₋ₓSrₓTiO₃ is the archetype of electrically tunable materials. While the ability to adjust T_{C} in a wide temperature range, including room temperature, by controlling the amount of Sr-doping explains the success of the Ba₁₋ₓSrₓTiO₃ solid solution, the cubic aristotype of the ubiquitous perovskite structure with only two distinct cation sites still sets the benchmark for electrically tunable applications. This structural inflexibility becomes apparent, when tasks such as increasing tunability and reduction of the dielectric loss are addressed by nitrogen and acceptor doping with MgO, Al₂O₃, and other binary oxides, respectively, rather than engineering the intrinsic structural properties by targeted doping.

The influence of basic structural features such as the connectivity amongst TiO₆ octahedra in titanates offers a different path for tunable properties. In the basic cubic perovskite structure all TiO₆ octahedra are connected at corners, which results in Ti—Ti distances equivalent to the length of one unit cell. However, many other titanate structures contain edge-and face-sharing TiO₆ octahedra, and the influence of different connectivities amongst them on the electric field tunability of the dielectric constant remains unknown. The rich BaO—TiO₂ phase diagram provides several structural alternatives, including the monoclinic BaTi₂O₅, where the ferroelectricity is likewise induced by an off-center motion of Ti in the TiO₆ octahedra. The methods described herein demonstrate the magnitude of the anharmonic interaction between Ti-atoms in this compound in comparison to the perovskite structure, which enable a much lower dielectric permittivity, without sacrificing tunability. The large anharmonicity may be directly correlated to the much shorter Ti—Ti distances due to the existing of edge-sharing TiO₆ polyhedra. The structure-property relationship, which profoundly affects tunability, suggests a guiding motif for identifying other promising crystal structures.

An example method may comprise growing Ba—Ti—O thin films by atomic layer deposition (ALD) on (100)Si substrates possessing a native oxide layer and on Pt(111)/Ti/SiO₂/Si(100) substrates (e.g., as produced by Gmek Inc.) at 290° C., followed by post-deposition annealing at 750° C. for 6 h and for 48 h, with a heating and cooling rate of 2° C./min for each annealing. The example method may comprise annealing conducted in a sealed tube furnace with a static O₂ overpressure of 5 psi. The example method may comprise ALD carried out using a Picosun R200 Advanced Reactor. Absolut Ba (Air Liquide, bis(1,2,4 triisopropylcyclopentadienyl)Ba, Ba(ⁱPr₃Cp)₂), titanium-tetraisopropoxide (Alfa Aesar, Ti(ⁱOPr)₄, TTIP), and deionized H₂O as precursors for Ba, Ti, and O, respectively. The example method may comprise using a diffractometer (e.g., Rigaku Smartlab™) equipped with a Cu-source for X-ray reflectivity (XRR) and grazing incidence X-ray diffraction (GI-XRD) measurements. The example method may comprise collecting Raman spectra in backscattering configuration z(x,x+y)z̅ using a single monochromator (e.g., XploRA, Horiba Jobin-Yvon, Edison, NJ). The example method may comprise conducting transmission electron microscopy (TEM) and selected area electron diffraction (SAED) utilizing a microscope (e.g., JEOL JEM2100) operated at 200 kV. The example method may comprise measuring the composition of the thin film sample utilizing a scanning electron microscope (SEM) (e.g., Zeiss Supra 50VP) equipped with an energy dispersive detector (EDS) and may reveal a Ba/Ti-ratio of 0.5. For dielectric measurements the bottom Pt electrode may be contacted using Ag-paste, and lithographically defined ≈80 nm-thick top Pt electrodes may be sputtered at room temperature prior to the annealing step. The samples may be placed in a probe station (e.g., Lakeshore Cryotronics TTP4) and measured at room temperature within 10 kHz-1 MHz frequency range (e.g., Keithley SCS-4200). The example method may comprise carrying out density functional theory (DFT) calculations using the local density approximation (LDA) of Perdew and Zunger for the exchange-correlation functional, as implemented in the Quantum Espresso (QE) package. The example method may comprise carrying out initial ionic coordinates relaxation of the 48 atoms unit cell using the pseudopotentials from the GBRV pseudopotential database to represent effect of the nuclei and the core electrons on the valence electrons. Self-consistent calculations may be performed for the evaluation of the electronic structure using a 4×4×4 k-point grid in the Brillouin zone. Raman calculations may be performed at the Γ k-point. Both self-consistent and Raman calculations may be performed using the optimized norm-conserving Vanderbilt pseudopotential.

Additional information on film synthesis, TEM characterization, and Table 2, comparing DFT-calculated and observed Raman mode energies for BaTi₂O₅, as well as fits to the Johnson model for electric field dependent capacitance for Ba_{0.25}Sr_{0.75}TiO₃ thin films at different temperatures and fitting results are provided below.

### 3.1. Structural Properties

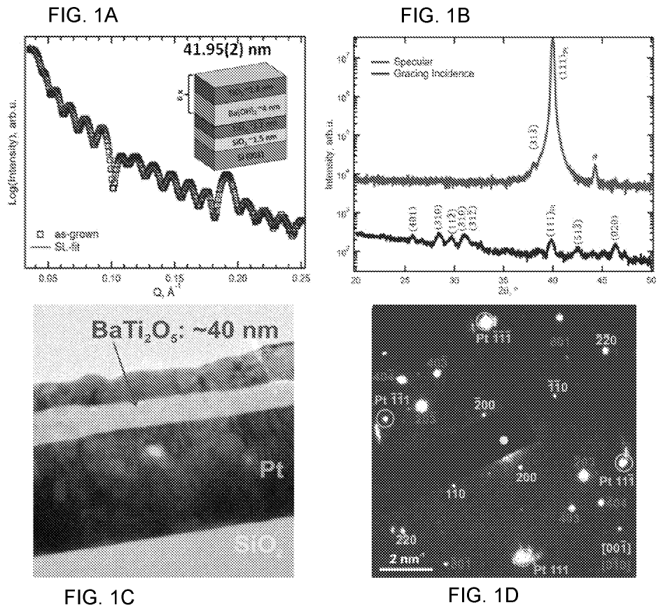

Atomic layer deposition of the amorphous film may be conducted utilizing a superstructure approach based on alternating TiO₂ and Ba(OH)₂ layers described elsewhere. Briefly, an initial TiO₂ layer of 1.21(1) nm thickness may be deposited to ensure conformal growth of the subsequent layers. Here, the figure in parenthesis provides the so-called standard uncertainty or estimated standard deviation, which is frequently used to provide crystallographic information. In case of 1.21(1) nm thickness, it means 1.21±0.01 nm. The Ti-precursor (TTIP) used for the growth of these films reacts readily with surface OH⁻ groups. Starting with a TiO₂ layer ensures a good adhesion and a better control of the film growth in terms of uniformity as compared to starting with the Ba-precursor (Ba(ⁱPr₃Cp)₂) which is more difficult to control on the initial surface of the substrate. Then, alternating layers of Ba(OH)₂ and TiO₂ with thicknesses of 3.97(1) nm and 2.82(1) nm may be grown. The total pulse sequence may be (TTIP-H₂O)×40+[(4×Ba(ⁱPr₃Cp)₂-H₂O)×25+(TTIP-H₂O)×100]×6, resulting in a total film thickness of 41.95(2) nm. This stacking sequence of alternating blocks may be reflected in the XRR-data of the as-grown film and the close resemblance to a fitted model may confirm the successful growth of a superstructure (FIG. 1a).

The polycrystalline nature of the films may be confirmed by X-ray diffraction of a 100 nm thick film exposed to similar annealing conditions (FIG. 1b). The grazing incidence scan reveals a variety of diffraction maxima consistent with the BaTi₂O₅ structure and random orientation of crystallites. In specular conditions, the differences to physical vapor deposited films becomes apparent as only a weak peak close to the (111)-Pt peak, which may be attributed to the (313)-reflection. Cross section TEM analysis confirms a ≈40 nm thick BaTi₂O₅ film (FIG. 1c). The selected area electron diffraction (SAED) image for this region (FIG. 1d) confirms the polycrystalline nature of the film.

FIG. 1 shows example structural characterization of BaTi₂O₅ thin films. (a) XRR data of the as-grown film on a Si-substrate. The line represents the fitting result to the superstructure model shown as an inset; (b) Specular and Grazing incidence XRD for a 100 nm-thick film on a Pt(111)/Ti/SiO₂/Si(100) substrate after annealing at 750° C. for 6 h. The material number for BaTi₂O₅ is mp-558159 in the Materials Project. The peak marked ‘#’ in the specular XRD is the peak from the XRD-stage; (c) BF-TEM cross section of the structure after annealing at 750° C. for 6 h; (d) SAED (selective area electron diffraction) revealing diffraction spots corresponding to two different crystallites. The respective Miller indices and zone axes of the 2 distinct BaTi₂O₅ crystallites are provided in red and gold. The spots marked with blue circles correspond to the Pt bottom electrode.

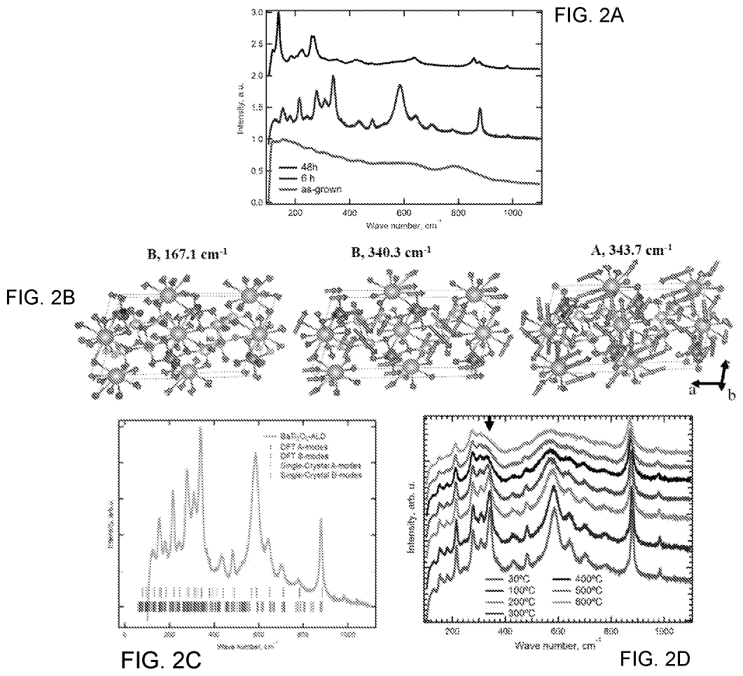

Raman scattering spectroscopy unambiguously confirms the formation of BaTi₂O₅ after annealing at 750° C. for 6 h (FIG. 2a), and all observed Raman modes can be assigned to BaTi₂O₅. However, annealing for 48 h clearly demonstrates that BaTi₂O₅ is only kinetically stable at this temperature as longer annealing results in decomposition of this phase. The calculations reveal that the peak at 342 cm⁻¹ is actually composed of two distinct modes, one with B-symmetry at 340.3 cm⁻¹ and one with A-symmetry at 343.7 cm⁻¹. A closer inspection of these modes reveals that in both cases, significant mode eigenvector components are found for the Ti-atoms, which exhibit the largest ferroic displacement within the 3 distinct TiO₆ octahedra. While the eigenvector components displace the Ti-atoms symmetrically in the a-direction for the mode at 340.3 cm⁻¹, asymmetric displacement of the 4 Ti-atoms along the c-direction is present in the mode at 343.7 cm⁻¹. In both cases, some oxygen atoms also show larger eigenvector components (FIG. 2b). Analysis of the eigenvector displacement components for all 144 modes shows that the largest displacement of these Ti-atoms is found for the B-mode at the frequency of 5.0093 THz. However, at the corresponding Raman shift of 167.09 cm⁻¹, neither the BaTi₂O₅ film nor the single crystal exhibit a noticeable intensity above the baseline. This observed behavior may be due to a plethora of additional modes in close proximity to the Raman shift (Table 2). For the peak at 585 cm⁻¹, an even more complex scenario with several vibrational modes contributing to the experimentally measured intensity is observed (FIG. 2c).

FIG. 2 shows example Raman scattering characterization of BaTi₂O₅ thin films. (a) Raman spectra of a ≈40 nm thick film following deposition at 290° C. (bottom), after annealing at 750° C. for 6 h (middle), and after annealing at 750° C. for 48 h (top), respectively; (b) Selected vibrational modes with symmetry and calculated wavenumber. The DFT-calculated relaxed structure for BaTi₂O₅ with calculated forces on each atom is provided. Ba-atoms are displayed in green, O-atoms in red, Ti-atoms in light blue (Ti2, Ti3) and pink (Ti1). Note that Til exhibits the largest displacement from the TiO₆-center along the polar b-axis. All force arrows are plotted in red (Ba, Ti, O) and for Ti1-atoms in blue; (c) Raman spectrum of the 40 nm thick ALD-grown film after annealing at 750° C. for 6 h and the position of A-and B-modes from DFT calculations and from data collected for a BaTi₂O₅ single crystal in different measurement geometries; (d) Raman spectrum as a function of temperature. The black arrow indicates the Raman peak at 342 cm⁻¹ which exhibits the most pronounced temperature dependence.

### 3.2. Lattice Dynamical Properties

The structural change associated with the ferroelectric to paraelectric phase transition for the 40 nm thick BaTi₂O₅ thin film may be probed by Raman scattering over the temperature range of 30 to 600° C. (FIG. 2d). The temperature dependence is qualitatively consistent with previous measurements of single crystals and polycrystalline thin films. Between 100 cm⁻¹ and 1100 cm⁻¹ two strong Raman bands at 342 cm⁻¹ and 585 cm⁻¹ may be observed at room temperature, with many smaller intensity bands. Both strong modes soften and broaden upon heating, as expected, but the peak at 342 cm⁻¹ shows a significant change in behavior at ˜400° C. as the mode intensity drastically decreases. By contrast, the peak at 585 cm⁻¹ exhibits no significant change in intensity or position beyond the expected softening and broadening with temperature. A large number of modes may vanish in a single crystal at the ferroelectric transition temperature (T_{C}≈470° C.). A group theoretical analysis of Raman and IR-modes for the ferroelectric (SG: C2) and paraelectric (SG: C2/m) structures may corroborate this observation as a total of 34 A+35 B Raman-and IR-active optical modes split into 12 Aᵤ+24 Bᵤ IR-active and 22 A_{g}+11 B_{g} Raman-active modes upon introducing an inversion center for the high temperature phase. As modes, which may be simultaneously IR-and Raman-active, carry a polarization an additional frequency splitting between longitudinal and transverse waves, resulting in a total number of 144 distinguished frequencies. This symmetry-based prediction may be confirmed by DFT calculations that obtain 144 vibrational modes at the T-point (Table 2). Since the peaks of the polycrystalline film are wider due to contributions to the intensity from modes of both symmetries, a precise determination of Te may be impossible or not feasible. However, the similarities in the temperature dependence to the single crystal data, e.g. for the peak at 342 cm⁻¹. strongly suggest a similar structural change in the same temperature range. A broadening of the phase transition, a commonly observed phenomenon in ferroelectric thin films, which may be attributed to various scaling effects, most prominently grain size, film thickness, and clamping to the substrate, could be present, but cannot be clearly resolved due to the complexity of the structure. Nevertheless, the symmetry change associated with the phase transition from the ferroelectric to the paraelectric state, from the non-centrosymmetric (SG: C2) to the centrosymmetric structure (SG: C2/m) may be clearly observed for the 40 nm thick polycrystalline thin film in the temperature region between 400 and 500° C.

### 3.3. Dielectric Properties

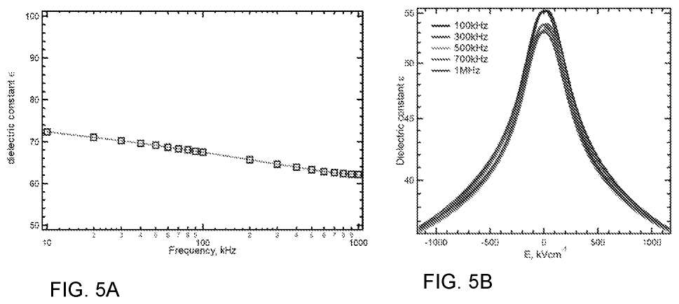

The measured dielectric constant, ε, of the BaTi₂O₅ thin film is ≈70 (FIG. 5a), similar to that reported for a bulk single crystal annealed in air, a 440 nm thick film synthesized by the sol-gel method, and laser chemical vapor deposited films of ≈8.5 μm thickness. The apparent lack of a strong thickness dependence of the dielectric constant for BaTi₂O₅ at room temperature is markedly different from the pronounced decrease of ε for thin films of the perovskite BaTiO₃ as a function of film thickness as well as grain size, in particular below 100 nm. This difference may be associated with Te located far above room temperature for BaTi₂O₅, which should also result in a smaller temperature coefficient of capacitance. Measured dielectric loss is <0.03, which is reasonable given the structure. The electric field dependence of the dielectric constant at different frequencies is displayed in FIG. 5b. The typical butterfly-shape signifying ferroelectric behavior is not present, and there are no distinct changes as a function of frequency. However, a close inspection of the field dependence of the dielectric constant reveals weak indications for a coercive field around 30-40 kVcm⁻¹, which is comparable to coercive fields below 100 kVcm⁻¹ reported for 500 nm thick BaTi₂O₅ films synthesized by the sol-gel method.

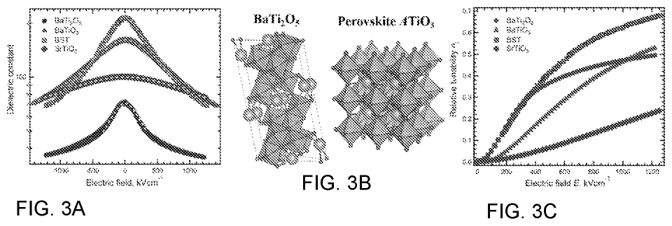

Although the ferroelectric phase transition in BaTi₂O₅ is manifested by an off-center displacement of the Ti-atom in one of three TiO₆-octahedra in a similar manner as in the perovskite BaTiO₃, the different bonding environment among these polyhedra in this structure-type may result in fundamental differences in the structure-property relationships. One striking difference is the much shorter distance between the closest Ti-atoms of only 2.91 Å as compared to ≈4 Å in the perovskite ATiO₃ structure (A=Ba, Pb, Sr, etc.). In order to examine potential differences in the mechanisms involved in the non-linear response of the permittivity (ε) to an electric biasing field (E), the ε-E dependence of the 40 nm thick BaTi₂O₅ film is compared to the ALD-grown 50 nm thick BaTiO₃ (BTO), 40 nm thick SrTiO₃ (STO) films, and a 40 nm thick Ba_{0.7}Sr_{0.3}TiO₃ (BST) film synthesized by chemical vapor deposition (CVD). The dielectric constant as a function of electric field for all three films is displayed in FIG. 3a. Based on Devonshire's theory, Johnson proposed a phenomenological model describing the field-dependence of the dielectric permittivity:

$$ε ( E ) = \frac{ε ( 0 )}{{( 1 + α {ε ( 0 )}^{3} {E}^{2} )}^{1 / 3}} \qquad ( 1 )$$

Here, ε(E) and ε(0) are the dielectric constant at the applied electric field E and at zero biasing field, i.e. at E=0, respectively, and α is the anharmonic coefficient. Note that dielectric constant is ε(0). This phenomenological parameter is correlated to the anharmonic interaction between the Ti-ions in the structure. The Johnson model is applicable to the paraelectric state, however, as thin films lack hysteretic behavior, fits to equation (1) should allow discerning differences among the four samples. While the model can describe the measured voltage range for all perovskite-based films, in case of BaTi₂O₅ only the electric field range below ±340 kVcm⁻¹ follows the Johnson model. Moreover, α is 28 times larger for BaTi₂O₅, while it only varies by a factor of ≈2 among the perovskite-based films (Table 1), emphasizing the impact of the bonding amongst the TiO₆ octahedra on the resulting electric field dependence of ε rather than the different cations in the A-site of ATiO₃.

FIG. 3 shows example dielectric tunability of the BaTi₂O₅ thin film. FIG. 3 shows (a) Dielectric constant as a function of applied electric field for the 40 nm thick BaTi₂O₅ film, a 55 nm thick ALD-grown, polycrystalline BTO film, a 40 nm thick ALD-grown polycrystalline STO film (all three measured at 100 kHz), and a 40 nm thick BST film grown by CVD (measured at 1 kHz). The dashed lines correspond to fits to the Johnson model (equation 1). FIG. 3 shows (b) Crystal structures of BaTi₂O₅, and a cubic perovskite ATiO₃ with the TiO₆-octahedra (blue), barium (green), and oxygen (red). FIG. 3 shows (c) Relative tunability, nᵣ, as a function of applied field, E, for the 40 nm thick BaTi₂O₅ film, a 55 nm thick ALD-grown, polycrystalline BTO film, a 40 nm thick ALD-grown STO film (all three measured at 100 kHz), and a 40 nm thick BST film grown by CVD (measured at 1 kHz).

Table 1 shows fitting results for the ε-E dependence of the BaTi₂O₅, BaTiO₃(BTO), SrTiO₃ (STO) and Ba_{0.7}Sr_{0.3}TiO₃ (BST) films displayed in FIG. 3a to equation (1). Also, the volumes of the TiO₆ octahedra in the cubic perovskite structure and the paraelectric structure of BaTi₂O₅ calculated using ToposPro are provided.

TABLE 1

| Film | ∈(0) | α, cm²kV⁻² | TiO₆-volume, Å³ |
|---|---|---|---|
| BaTi₂O₅ | 71 | 160.2*10⁻¹³ | 10.48/10.36/10.41^{a} |
| BTO | 162 | 4.2*10⁻¹³ | 10.731^{b} |
| BST | 215 | 5.7*10⁻¹³ | 10.485^{b} |
| STO | 100 | 2.7*10⁻¹³ | 9.925^{b} |

^{a}the BaTi₂O₅ structure contains three distinct Ti-sites;
^{b}cubic lattice parameters 4.008 Å (BTO), 3.9771 Å (BST), and 3.905 Å (STO) were used.

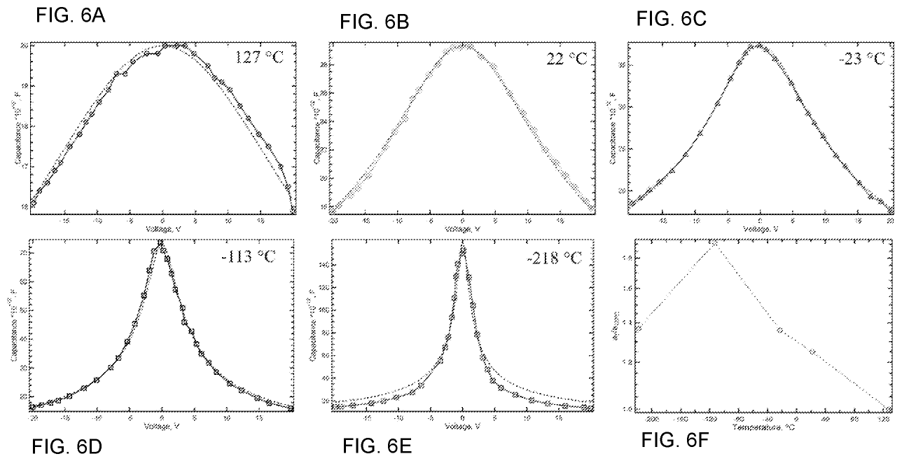

To disentangle different influences on α, an example method may comprise inspection of the variation observed for the structurally closely related perovskite thin films. While the BTO and STO film were crystallized with a post annealing treatment at 700° C. or 750° C., and are polycrystalline films with randomly oriented nanosized grains, BST film was deposited at 640° C. and contains strongly {100}-textured columnar grains. This orientation could account for the increased value of α observed for the BST thin film as most dipoles produced within the TiO₆ octahedra may be oriented perpendicular to the applied bias field. Another reason for the larger anharmonic parameter is the close vicinity of the measurement conditions to T_{C} (27° C.) for the BST film. In order to evaluate the influence of T_{C} on α for the same film, an example method may comprise fitting field dependent capacitance data of 560 nm thick PLD-grown Ba_{0.25}Sr_{0.75}TiO₃ films collected in a wide temperature range from −218° C. to 127° C. including the bulk T_{C}≈−113° C. for this composition (FIG. 6). Indeed, the highest value for α was found for the data collected at −113° C., however, it only increased by a factor <2 compared to 127° C. (Table 3). Assuming that the tetragonal distortion for BTO thin films is negligible, the smaller α of STO compared to BTO may arise from the reduced volume of the TiO₆ octahedron (Table 1), which may hinder anharmonic interactions between the Ti-atoms and reduce the induced polarization.

Exploring the reasons behind the greatly enhanced anharmonic parameter observed for the BaTi₂O₅ thin film further, the volume of the TiO₆ octahedra may be ruled out, as they are within the range of the perovskite compounds (Table 1). However, several structural influences may be considered. First, the Raman spectra (FIG. 2d) imply the presence of Ti-displacement in the BaTi₂O₅ thin films similar to ferroelectric BaTiO₃ for one of the three distinct Ti-sites, and this displacement may potentially enhance the anharmonic response to the field bias. Second, the higher Ti/Ba ratio resulting in a 30% increased volume fraction of Ti-atoms in BaTi₂O₅ compared to the perovskite structure. Third, the connectivity amongst the Ti-polyhedra is more complex in case of BaTi₂O₅ (FIG. 3b): while in the perovskite ATiO₃ structure all TiO₆ units exclusively share corners, all three Ti-polyhedra in BaTi₂O₅ are also connected via edges to neighboring units. This results in a much closer distance between neighboring Ti-atoms of 2.91 Å in BaTi₂O₅, while the closest Ti—Ti distance in the perovskite structure is equivalent to the lattice parameter (Table 1). The results presented here strongly suggest that the connectivity amongst the TiO₆ octahedra governs the observed behavior as the larger volume fraction of Ti-atoms as well as the Ti-displacement (at least for the perovskite Ba_{0.25}Sr_{0.75}TiO₃) are shown to be unlikely explanations to account for a two orders of magnitude enhancement of the anharmonic interaction.

The sensitivity of the relative tunability,

$${n}_{r} = \frac{ε ( 0 ) - ε ( E )}{ε ( 0 )} ,$$

to the bias field is larger for the BaTi₂O₅ film compared to the ALD-grown perovskite films and is equivalent to the BST film, which has a 3 times larger dielectric constant, below 400 kVcm⁻¹ (FIG. 3c). This high sensitivity of nr may be a particularly applicable to voltage tunable applications, where a fast response and/or low electric fields are advantageous. The low dielectric permittivity of the BaTi₂O₅ film, ≈65% lower than BST films of comparable thickness, is beneficial for impedance matching for high power applications.

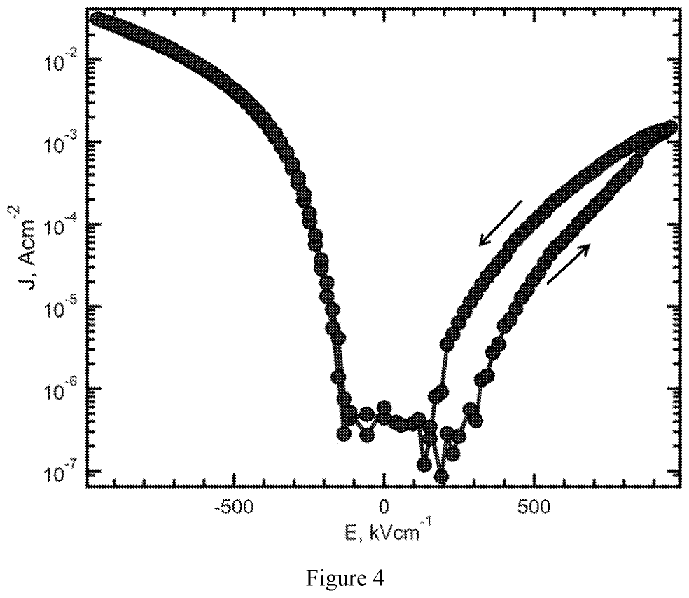

The leakage current density, J, as a function of applied electric field, E, determined from a BaTi₂O₅-based MIM-capacitor is displayed in FIG. 4. Note that the electric field may be applied in the following manner: a positive field up to 1000 kVcm⁻¹ may be applied starting from zero, then reduced again, followed by applying a negative field of −1000 kVcm⁻¹, and reduction back to zero. The field dependence of J exhibits a subtle asymmetry for positive and negative bias indicating a dominating contribution of interfacial phenomena. Overall, the leakage current is in a comparable range to other thin films, in particular to ALD-grown BTO- and STO-based MIM-capacitors.

FIG. 4 shows leakage current density, J, as a function of applied electric field, E, for a 40 nm thick BaTi₂O₅ film.

### Synthesis

During ALD growth the source cylinders with separate gas lines to the deposition chamber may be kept at temperatures of 200° C., 115° C., and room temperature for Ba(ⁱPr₃Cp)₂, TTIP, and H₂O, respectively. The deposition temperature and base pressure may be 290° C. and 2-5 hPa. High purity N₂ (99.9999%) may serve as a carrier gas. The pulse and purge times for Ba(ⁱPr₃Cp)₂ may be 1.6 and 6 s, and 0.1 and 10 s for H₂O. The pulse sequence for the Ba—O subcycle may contain 4 consecutive Ba(iPr₃Cp)₂-pulses to ensure gas phase saturation in the deposition chamber followed by 1 water pulse for the Ba—O subcycle with a growth rate of 0.38(2) Å/Ba(ⁱPr₃Cp)₂-pulse. For the Ti—O subcycle the pulse and purge times may be 0.3 and 1 s for TTIP, and 1 and 3 s for H₂O in alternating sequence resulting in a growth rate of 0.30(2) Å. The overall deposition sequence may be (TTIP-H₂O)×40+[(4×Ba(ⁱPr₃Cp)₂-H₂O)×25+(TTIP-H₂O)×100]×6. Annealing may be conducted in a sealed tube furnace with a static O₂ overpressure of 5 psi. The samples may be kept at 750° C. for 6 h with a heating and cooling rate of 2° C./min for the annealing. Prolonged annealing at 750° C. (48 h) may reveal a partial decomposition, most likely into Ba₄Ti₁₃O₃₀, with residual BaTi₂O₅. This observation may be explained by a combination of two effects: i) although BaTi₂O₅ exhibits high kinetic stability, thermodynamically this compound is only stable between 1220 and 1230° C. and a decomposition into BaTiO₃ and Ba₄Ti₁₃O₃₀ is expected for thermodynamic equilibrium at 750° C., ii) at elevated temperatures Ti from the Pt(111)/Ti/SiO₂/Si(001) substrate may diffuse into the thin film sample and cause a shift in the cation ratio towards the Ti-richer phase Ba₄Ti₁₃O₃₀. Corresponding Raman spectra are shown in FIG. 2a.

### TEM Characterization

Insight into the morphology of the BaTi₂O₅ films may be gained from analysis of a TEM cross section (FIG. 1c). A cross section of the parallel plate-capacitor geometry structure with a ≈40 nm thick BaTi₂O₅ film sandwiched between bottom- and top-Pt electrodes is shown (Note that the top-Pt electrodes were deposited before annealing). A continuous BaTi₂O₅ film with slightly varying thickness may be observed and the polycrystalline nature may be apparent from randomly oriented grains within the cross section. In general, a higher density of crystalline material may be observed close to the bottom electrode indicating that the crystallite nucleation is initiated at the bottom electrode-film interface. Occasionally, larger crystallites extend from the bottom-to the top-electrode. The selected area electron diffraction (SAED) image for this region is displayed in FIG. 1d. The diffraction spots may be indexed to contributions of two BaTi₂O₅ crystallites confirming the polycrystalline nature of the thin film.

### Raman Shift

Table 2 shows calculated (144-3 translational modes) and observed Raman shifts for BaTi₂O₅ from DFT-calculations, Raman spectroscopy of an ALD-grown polycrystalline thin film, and of a single crystal. The measured peak maxima are inserted next to the closest calculated Raman shift (with similar symmetry in case of the single crystal data), symmetry of the vibrational modes is provided in Mulliken notation.

TABLE 2

| DFT, Raman | | Raman | Single crystal, | |
|---|---|---|---|---|
| shift, cm⁻¹ | Sym. | shift, cm⁻¹ | Raman shift, cm⁻¹ | Sym. |
| 59.4 | B | | | |
| 66.7 | A | | | |
| 67.9 | A | | | |
| 70.3 | B | | | |
| 74.3 | B | | | |
| 79.2 | B | | 80 | B |
| 82.3 | A | | 79 | A |
| 91.3 | A | | | |
| 94.3 | B | | | |
| 94.4 | B | | | |
| 98.5 | B | | 97 | B |
| 99.7 | A | | 97 | A |
| 102.5 | A | | | |
| 103 | A | | | |
| 110.9 | B | | | |
| 111.3 | B | | | |
| 119.6 | B | | | |
| 122.1 | A | | | |
| 128.6 | A | 127 | 130 | A |
| 131.1 | B | | 133 | B |
| 133.8 | A | | | |
| 138.6 | B | | | |
| 153.2 | B | | | |
| 153.7 | A | | | |
| 153.8 | B | | 155 | B |
| 154.1 | A | 155 | | |
| 157.2 | A | | | |
| 159.9 | A | | 161 | A |
| 165.5 | B | | 164 | B |
| 167.1 | B | | | |
| 168.3 | B | | | |
| 175.5 | B | | | |
| 178.3 | A | | | |
| 179.3 | B | 180 | | |
| 183.3 | A | | 185 | A |
| 185.9 | B | | 186 | B |
| 200.1 | B | | | |
| 203.1 | B | | | |
| 205.2 | A | | | |
| 211.5 | A | | | |
| 216 | A | 215 | | |
| 216.4 | A | | 218 | A |
| 217.1 | B | | 220 | B |
| 224 | B | | | |
| 232.5 | A | | | |
| 237.2 | B | | | |
| 240.4 | A | | | |
| 241.6 | B | 243 | 246 | B |
| 247.6 | A | | 245 | A |
| 259.5 | A | | | |
| 262.2 | B | | | |
| 263.1 | A | | | |
| 265.6 | A | | | |
| 265.8 | B | | | |
| 268.8 | B | | | |
| 270.6 | B | | | |
| 271.1 | A | | | |
| 276.5 | B | | | |
| 277.5 | B | | | |
| 278 | A | 279 | | |
| 280.7 | A | | 281 | A |
| 285.5 | B | | 285 | B |
| 287.5 | A | | | |
| 288.1 | B | | | |
| 295.9 | A | | | |
| 298.5 | B | | | |
| 307.2 | A | | | |
| 307.6 | B | | | |
| 308.8 | A | | | |
| 309.6 | B | 310 | | |
| 313.1 | B | | 313 | B |
| 314.4 | A | | 312 | A |
| 315.7 | A | | | |
| 319.8 | A | | | |
| 321.6 | B | | | |
| 322.8 | A | | 325 | A |
| 328.3 | A | | | |
| 329.5 | B | | | |
| 332 | A | | | |
| 333.8 | B | | | |
| 340.3 | B | 339 | 344 | B |
| 343.7 | A | | 344 | A |
| 348.8 | A | | | |
| 351.5 | A | | | |
| 356.4 | A | | | |
| 357.3 | B | | | |
| 362.4 | B | | | |
| 369.7 | B | 367 | | |
| 382 | A | | 377 | A |
| 386.4 | B | | 381 | B |
| 393.7 | A | | 394 | A |
| 404.2 | A | | | |
| 405.5 | B | | | |
| 407.1 | B | | | |
| 415.1 | A | 413 | 414 | A |
| 419.5 | B | | | |
| 420.2 | A | | | |
| 426.3 | B | | | |
| 427.9 | A | 434 | | |
| 451.5 | B | | 440 | A |
| 452 | A | | 441 | B |
| 452.7 | B | | | |
| 457.7 | A | | | |
| 459.9 | B | | | |
| 466.2 | B | | | |
| 477.3 | A | | | |
| 483.4 | A | 483 | | |
| 490.7 | A | | 489 | A |
| 491.1 | B | | 489 | B |
| 502.3 | B | | | |
| 514.8 | B | | | |
| 515.3 | B | | | |
| 522.7 | B | 523 | | |
| 527 | A | | | |
| 529.7 | A | | | |
| 534.7 | A | | | |
| 538.7 | A | | | |
| 541.8 | B | | | |
| 549.4 | A | | | |
| 549.6 | B | | | |
| 558.4 | A | | | |
| 594.9 | A | 584 | 589 | A |
| 595.4 | B | | 593 | B |
| 613 | B | | | |
| 619.4 | B | | | |
| 648.2 | B | 641 | 649 | B |
| 654 | A | | 648 | A |
| 662 | B | | | |
| 669.4 | A | 678 | | |
| 706.5 | B | 702 | 710 | B |
| 712.7 | A | | 711 | A |
| 716.5 | A | | | |
| 767.3 | B | | | |
| 775.5 | B | 778 | 782 | B |
| 787.8 | A | | 788 | A |
| 802 | A | | | |
| 805.2 | B | | | |
| 834.1 | B | | | |
| 843.6 | A | | | |
| 876.7 | B | 879 | 884 | B |
| 883.4 | A | | 885 | A |

### Dielectric Properties

FIG. 5 shows (a) Frequency dependence of the dielectric constant, ε, of a 40 nm thick BaTi₂O₅ film; (b) Electric field dependence of ε for different frequencies.

Table 3 shows results for the least squares fitting of C-V data of 560 nm thick PLD-grown Ba_{0.25}Sr_{0.75}TiO₃ film from Vorobiev et al. collected at different temperatures. Note, that a normalized anharmonic parameter αₙₒᵣₘ=α_{T}/α_{127° C.} is used.

TABLE 3

| Temperature, ° C. | αₙₒᵣₘ |
|---|---|
| 127 | 1 |
| 22 | 1.25 |
| −23 | 1.36 |
| −113 | 1.91 |
| −218 | 1.37 |

FIGS. 6a, 6b, 6c, 6d, and 6e show C-V data for a 560 nm thick PLD-grown Ba_{0.25}Sr_{0.75}TiO₃ film collected at different temperatures at a frequency of 1 MHz. The dashed lines correspond to least squares fit results using the Johnson model (equation 1 of the main text). FIG. 6f shows normalized anharmonic parameter as a function of temperature.

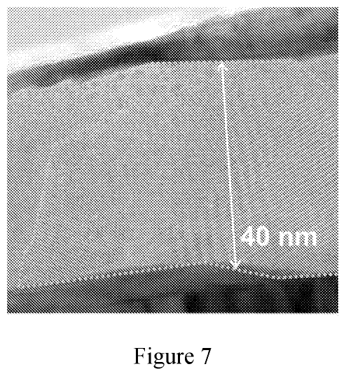

FIG. 7 shows a region with a large BaTi₂O₅ crystallite within the MIM structure. The present disclosure relates to at least the following aspects:

Aspect 1. A thin film comprising Ba—Ti—O configured to exhibit a structure where a distance of one or more neighboring Ti—Ti atoms is less than 3 Å.

Aspect 2. The thin film of aspect 1, wherein the thin film comprises BaTi₂O₅.

Aspect 3. The thin film of any one of aspects 1-2, wherein a sample of the thin film having a thickness of 40 nm exhibits a dielectric constant at zero field ε(0) of less than 100.

Aspect 4. The thin film of any one of aspects 1-2, wherein a sample of the thin film having a thickness of 40 nm exhibits a dielectric constant at zero field ε(0) of less than 90.

Aspect 5. The thin film of any one of aspects 1-2, wherein a sample of the thin film having a thickness of 40 nm exhibits a dielectric constant at zero field ε(0) of less than 80.

Aspect 6. The thin film of any one of aspects 1-5, wherein a sample of the thin film having a thickness of 40 nm exhibits an anharmonic coefficient α of greater than 100*10−13 cm2kV−2.

Aspect 7. The thin film of any one of aspects 1-5, wherein a sample of the thin film having a thickness of 40 nm exhibits an anharmonic coefficient α of greater than 110*10−13 cm2kV−2.

Aspect 8. The thin film of any one of aspects 1-5, wherein a sample of the thin film having a thickness of 40 nm exhibits an anharmonic coefficient α of greater than 120*10−13 cm2kV−2.

Aspect 9. The thin film of any one of aspects 1-5, wherein a sample of the thin film having a thickness of 40 nm exhibits an anharmonic coefficient α of greater than 130*10−13 cm2kV−2.

Aspect 10. The thin film of any one of aspects 1-5, wherein a sample of the thin film having a thickness of 40 nm exhibits an anharmonic coefficient α of greater than 140*10−13 cm2kV−2.

Aspect 11. The thin film of any one of aspects 1-5, wherein a sample of the thin film having a thickness of 40 nm exhibits an anharmonic coefficient α of greater than 150*10−13 cm2kV−2.

Aspect 12. The thin film of any one of aspects 1-5, wherein a sample of the thin film having a thickness of 40 nm exhibits an anharmonic coefficient α of greater than 160*10−13 cm2kV−2.

Aspect 13. A thin film comprising Ba—Ti—O configured to exhibit a dielectric constant at zero field ε(0) of less than 100 and an anharmonic coefficient α of greater than 100*10−13 cm2kV−2.

Aspect 14. A thin film comprising Ba—Ti—O configured to exhibit a dielectric constant at zero field (0) of less than 100 and an anharmonic coefficient α of greater than 110*10−13 cm2kV−2.

Aspect 15. A thin film comprising Ba—Ti—O configured to exhibit a dielectric constant at zero field ε(0) of less than 100 and an anharmonic coefficient α of greater than 120*10−13 cm2kV−2.

Aspect 16. A thin film comprising Ba—Ti—O configured to exhibit a dielectric constant at zero field ε(0) of less than 100 and an anharmonic coefficient α of greater than 130*10−13 cm2kV−2.

Aspect 17. A thin film comprising Ba—Ti—O configured to exhibit a dielectric constant at zero field ε(0) of less than 100 and an anharmonic coefficient α of greater than 140*10−13 cm2kV−2.

Aspect 18. A thin film comprising Ba—Ti—O configured to exhibit a dielectric constant at zero field ε(0) of less than 100 and an anharmonic coefficient α of greater than 150*10−13 cm2kV−2.

Aspect 19. A thin film comprising Ba—Ti—O configured to exhibit a dielectric constant at zero field ε(0) of less than 100 and an anharmonic coefficient α of greater than 160*10−13 cm2kV−2.

Aspect 20. A method of forming thin film of any one of aspects 1-19.

Aspect 21. The method of aspect 20, wherein the thin film is formed using atomic layer deposition.

In summary, the systems and methods disclosed herein demonstrate that phase-pure BaTi₂O₅ thin films of 40 nm thickness may be synthesized by atomic layer deposition of alternating Ba(OH)₂ and TiO₂ layers followed by a subsequent annealing step at 750° C. BaTi₂O₅ thin films exhibit a 65% lower zero-field permittivity owing to an almost two orders of magnitude enhancement in the anharmonic interaction between Ti-atoms, attributed to connectivity amongst TiO₆ octahedra in the structure and the resulting short distances between neighboring Ti-atoms. This structural feature is, thus far, an overlooked factor, which directly influences the electric field response of the permittivity, and is promising for its use in tunable dielectric applications where lower permittivity is advantageous. In general, the extraordinary high anharmonic interaction, together with the moderate dielectric constant deem thin-film BaTi₂O₅ an appealing alternative to currently considered compounds.

1. A thin film comprising Ba—Ti—O configured to exhibit a structure where a distance of one or more neighboring Ti—Ti atoms is less than 3 Å.

2. The thin film of claim 1, wherein the thin film comprises BaTi₂O₅.

3. The thin film of claim 1, wherein a sample of the thin film having a thickness of 40 nm exhibits a dielectric constant at zero field ε(0) of less than 100.

4. The thin film of claim 1, wherein a sample of the thin film having a thickness of 40 nm exhibits a dielectric constant at zero field ε(0) of less than 90.

5. The thin film of claim 1, wherein a sample of the thin film having a thickness of 40 nm exhibits a dielectric constant at zero field ε(0) of less than 80.

6. The thin film of claim 1, wherein a sample of the thin film having a thickness of 40 nm exhibits an anharmonic coefficient α of greater than 100*10⁻¹³ cm²kV⁻².

7. The thin film of claim 1, wherein a sample of the thin film having a thickness of 40 nm exhibits an anharmonic coefficient α of greater than 110*10⁻¹³ cm²kV⁻².

8. The thin film of claim 1, wherein a sample of the thin film having a thickness of 40 nm exhibits an anharmonic coefficient α of greater than 120*10⁻¹³ cm²kV⁻².

9. The thin film of claim 1, wherein a sample of the thin film having a thickness of 40 nm exhibits an anharmonic coefficient α of greater than 130*10⁻¹³ cm²kV⁻².

10. The thin film of claim 1, wherein a sample of the thin film having a thickness of 40 nm exhibits an anharmonic coefficient α of greater than 140*10⁻¹³ cm²kV⁻².

11. The thin film of claim 1, wherein a sample of the thin film having a thickness of 40 nm exhibits an anharmonic coefficient α of greater than 150*10⁻¹³ cm²kV⁻².

12. The thin film of claim 1, wherein a sample of the thin film having a thickness of 40 nm exhibits an anharmonic coefficient α of greater than 160*10⁻¹³ cm²kV⁻².

13. A thin film comprising Ba—Ti—O configured to exhibit a dielectric constant at zero field ε(0) of less than 100 and an anharmonic coefficient α of greater than 100*10⁻¹³ cm²kV⁻².

14. (canceled)

15. (canceled)

16. (canceled)

17. (canceled)

18. (canceled)

19. (canceled)

20. (canceled)

21. (canceled)

22. The thin film of claim 13, wherein a sample of the thin film exhibits an anharmonic coefficient α of greater than 110*10⁻¹³ cm²kV⁻².

23. The thin film of claim 13, wherein a sample of the thin film exhibits an anharmonic coefficient α of greater than 120*10⁻¹³ cm²kV⁻².

24. The thin film of claim 13, wherein a sample of the thin film exhibits an anharmonic coefficient α of greater than 130*10⁻¹³ cm²kV⁻².

25. The thin film of claim 13, wherein a sample of the thin film exhibits an anharmonic coefficient α of greater than 140*10⁻¹³ cm²kV⁻².

26. The thin film of claim 13, wherein a sample of the thin film exhibits an anharmonic coefficient α of greater than 150*10⁻¹³ cm²kV⁻².

27. A method of forming a thin film, wherein the formed thin film may comprise Ba—Ti—O configured to exhibit a structure where a distance of one or more neighboring Ti—Ti atoms is less than 3 Å.

28. The method of claim 27, wherein the thin film is formed using atomic layer deposition.
